(19) United States
(12) Patent Application Publication
(10) Pub. No.: US 2026/0247795 A1
(43) Pub. Date: Aug. 20, 2026

(54) THERMAL MANAGEMENT FOR PEROVSKITE ELECTRONIC DEVICES

(71) Applicant: The Trustees of Princeton University, Princeton, NJ (US)

(72) Inventors: Barry P. Rand, Princeton, NJ (US); Lianfeng Zhao, Clemson, SC (US); Stephen Chou, Princeton, NJ (US)

(21) Appl. No.: 17/912,982

(22) PCT Filed: Apr. 7, 2021
(86) PCT No.: PCT/US2021/026153

§ 371 Date: Sep. 20, 2022

Related U.S. Application Data
(60) Provisional application No. 63/006,792, filed on Apr. 8, 2020.

(51) Int. Cl. H10K 50/87; H05B 45/32; H05B 45/56; H05B 45/60; H10K 50/155; H10K 50/165; H10K 71/30; H10K 85/10; H10K 85/30; H10K 85/50; H10K 85/60

(52) U.S. Cl. CPC H10K 50/87; H05B 45/32; H05B 45/56; H05B 45/60; H10K 50/155; H10K 50/165; H10K 71/30; H10K 85/111; H10K 85/344; H10K 85/50; H10K 85/60; H10K 85/622; H10K 85/626

(57) ABSTRACT

Provided is a perovskite light emitting diode that may include a substrate, a hole-transport layer disposed over the substrate, a perovskite layer disposed over the hole-transport layer, an electron-transport layer disposed over the perovskite layer, and an electrode disposed over the electron-transport layer. The perovskite light emitting diode may be thermally managed using one or more thermal management strategies to reduce Joule heating and increase heat dissipation. Four such thermal management strategies are disclosed. Other embodiments are disclosed and additional embodiments are also possible.

### CROSS-REFERENCE TO RELATED APPLICATION(S)

This application is based on and claims priority to U.S. Provisional Application No. 63/006,792, filed on Apr. 8, 2020, the disclosure of which, including the appendix, is incorporated by reference herein in its entirety.

### UNITED STATES GOVERNMENT RIGHTS

This invention was made with government support under Grant No. FA-9550-18-1-0037 awarded by the Air Force Office of Scientific Research. The government has certain rights in the invention.

### BACKGROUND

### Technical Field

The instant disclosure generally relates to thin film semiconductor devices, in particular perovskite light emitting diodes (LEDs). More specifically, in one or more embodiments, it is directed to perovskite LEDs in which one or more thermal management strategies are implemented.

### Background Art

Research and development of both inorganic and organic LEDs have intensified in recent years due to the increasing proliferation of LEDs in commercial applications such as display technology and lighting technology. For LED technology to be practical and competitive with existing technology, for example for a LED light bulb to be competitive with an incandescent light bulb, long lifetime of the LED, particularly at high radiance, is required. In particular, microLED technology, which has attracted growing interest from the display industry in recent years, requires higher brightness that only devices made from inorganic III-V materials are capable of reaching to date. Despite rapid improvement in performance, perovskite LEDs with brightness comparable to inorganic LEDs have yet to be manufactured. One source of this difficulty is that the external quantum efficiency (EQE) of perovskite LEDs typically decreases at high current densities or brightness, an effect known as EQE roll-off. The precise causes of EQE roll-off remain a topic for research, but have been attributed to Auger recombination, electrical field-induced quenching, Joule heating, and/or charge imbalance. Furthermore, operational lifetime decreases dramatically at high current densities, making it difficult for perovskite LEDs to achieve both high brightness and long lifetime.

The above information is presented as background information only to assist with an understanding of the instant disclosure. No determination has been made, and no assertion is made, as to whether any of the above might be applicable as prior art with regard to the instant disclosure.

### SUMMARY

As explained above, a need exists in the art to limit the EQE roll-off of perovskite LEDs and to extend their lifetimes, particularly at high brightness or high current densities. In the instant disclosure, it is shown that elevated temperature caused by Joule heating is a major factor contributing to device degradation and EQE roll-off. Accordingly, it is an object of the instant disclosure to provide perovskite LEDs in which one or more thermal management strategies are implemented. As further explained below, perovskite LEDs incorporating these thermal management strategies exhibit improved performance such as improved EQE roll-off and improved lifetimes, even at high brightness.

In one embodiment of the instant disclosure, there is provided a perovskite light emitting diode that includes a substrate, a hole-transport layer disposed over the substrate, a perovskite layer disposed over the hole-transport layer, an electron-transport layer disposed over the perovskite layer, and an electrode disposed over the electron-transport layer. The perovskite light emitting diode may be thermally managed to reduce Joule heating and increase heat dissipation.

In another embodiment of the instant disclosure, there is provided a perovskite light emitting diode that includes a sapphire substrate, a hole-transport layer disposed over the substrate, the hole-transport layer including poly(4-butyl-triphenylamine-4′, 4″-diyl) (polyTPD) and is p-doped with 2,3,5,6-tetrafluoro-7,7,8,8-tetracyano-quinodimethane (F₄-TCNQ), a perovskite layer disposed over the hole-transport layer, an electron-transport layer disposed over the perovskite layer, the electron-transport layer including phenyldi(pyren-2-yl)phosphine oxide (POPy₂) and is n-doped with (penta-methylcyclopentadienyl)(1,3,5-trimethylbenzene)ruthenium dimer ([RuCp*Mes]₂), an electrode disposed over the electron-transport layer, a heat spreader disposed over the electrode, the heat spreader including a graphite sheet with an insulating acrylic adhesive layer or a polycrystalline diamond, a metallic heat sink disposed over the heat spreader, and a control circuit configured to drive the perovskite light emitting diode with electrical pulses. The device area of the perovskite light emitting diode may be in a narrow line shape.

In yet another embodiment of the instant disclosure, there is provided a method of fabricating a perovskite light emitting diode that includes preparing a perovskite precursor solution by dissolving methylammonium iodide (MAI), lead iodide (PbI₂), and benzylammonium iodide (PMAI) in dimethylformamide (DMF), cleaning a substrate and treating the substrate with O₂ plasma, spin-coating a hole-transport layer onto the substrate followed by thermal annealing, spin-coating a perovskite layer onto the hole-transport layer, solvent-quenching the perovskite light emitting diode prior to deposition of an electron-transport layer, and thermally evaporating the electron-transport layer onto the perovskite layer.

Other aspects and advantages of the instant disclosure will be apparent from the accompanying drawings, and the detailed description that follows.

### BRIEF DESCRIPTION OF THE DRAWINGS

For a more complete understanding of the instant disclosure and the advantages thereof, reference is now made to the following description taken in conjunction with the accompanying drawings, wherein like reference numerals represent like parts, in which: FIG. 1 is a block diagram illustrating an example of a perovskite LED according to one embodiment.

FIG. 2A illustrates the molecular structure of polyTPD according to one embodiment.

FIG. 2B illustrates the molecular structure of F₄-TCNQ according to one embodiment.

FIG. 2C illustrates the molecular structure of POPy₂ according to one embodiment.

FIG. 2D illustrates the molecular structure of [RuCp*Mes]₂ according to one embodiment.

FIG. 3 is an energy-level diagram illustrating p-doping mechanism of F₄-TCNQ for polyTPD according to one embodiment.

FIG. 4A is a graph illustrating current density-voltage curves for doped and undoped perovskite LEDs according to certain embodiments.

FIG. 4B is a graph illustrating radiance-voltage curves for doped and undoped perovskite LEDs according to certain embodiments.

FIG. 4C is a graph illustrating EQE-current density curves for doped and undoped perovskite LEDs according to certain embodiments.

FIG. 4D is a graph illustrating lifetime tests for doped and undoped perovskite LEDs according to certain embodiments.

FIG. 5A is a graph illustrating radiance-current density curves for perovskite LEDs with various geometries, substrate, and with or without heat spreaders and heat sinks according to certain embodiments.

FIG. 5B is a graph illustrating EQE-current density curves of perovskite LEDs with various geometries, substrate, and with or without heat spreaders and heat sinks according to certain embodiments.

FIG. 5C is a graph illustrating radiance-current density curves for perovskite LEDs with sapphire substrate, various geometries, and with or without heat spreaders and heat sinks according to certain embodiments.

FIG. 5D is a graph illustrating EQE-current density curves of perovskite LEDs with sapphire substrate, various geometries, and with or without heat spreaders and heat sinks according to certain embodiments.

FIG. 6 is a schematic diagram illustrating a SiO₂ patterning layer with a hole that defines device area according to one embodiment.

FIG. 7A is a graph illustrating time evolution of the normalized EQE of perovskite LEDs at a constant current density of 100 mA/cm² according to certain embodiments.

FIG. 7B is a graph illustrating time evolution of the normalized EQE of perovskite LEDs at a constant current density of 800 mA/cm² according to certain embodiments.

FIG. 7C is a graph illustrating carrier temperatures extracted from high-energy electroluminescence (EL) tails according to the generalized Planck equation for perovskite LEDs with various geometries and heat spreaders as a function of constant current density according to certain embodiments.

FIG. 7D is a graph illustrating time evolution of the normalized EQE of a perovskite LED under pulsed operation at 800 mA/cm² according to an embodiment.

FIG. 8A is a graph illustrating high energy portion of the EL spectra of perovskite LEDs with device areas of 10 mm² driven at various constant current densities according to certain embodiments.

FIG. 8B is a graph illustrating high energy portion of the EL spectra of perovskite LEDs with device areas of 2.5 mm² driven at various constant current densities according to certain embodiments.

FIG. 8C is a graph illustrating high energy portion of the EL spectra of perovskite LEDs with device areas of 2.5 mm² with graphite heat spreader and copper heat sink driven at various constant current densities according to certain embodiments.

FIG. 9A is a graph illustrating normalized radiance-time curves for various perovskite LEDs driven by a 700 A/cm² pulse with a pulsing width of 800 ns according to certain embodiments.

FIG. 9B is a graph illustrating radiance-current density curves of various perovskite LEDs driven in pulsed mode according to certain embodiments.

FIG. 9C is a graph illustrating EQE-current density curves of various perovskite LEDs driven in pulsed mode according to certain embodiments.

FIG. 10 is a flowchart illustrating a method of fabricating a perovskite LED according to an embodiment.

### DETAILED DESCRIPTION

The following is a detailed description of certain embodiments chosen to provide illustrative examples of how the disclosed invention may preferably be implemented. The scope of the disclosed invention is not limited to the specific embodiments described herein.

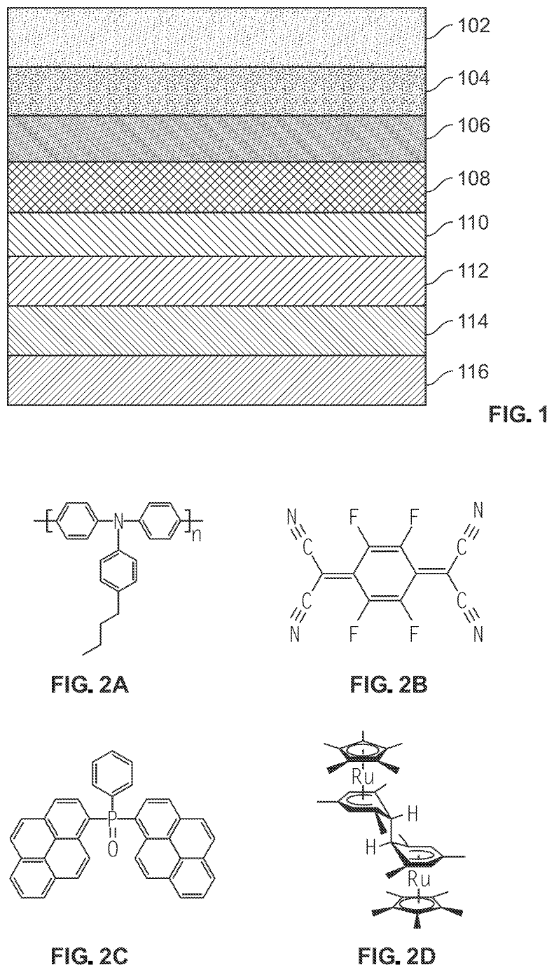

FIG. 1 is a block diagram illustrating an example of a perovskite LED according to one embodiment. The perovskite LED includes a substrate 116. The substrate 116 may be any suitable substrate that provides desired structural properties. The substrate may be flexible or rigid, planar or non-planar. The substrate may be transparent, translucent, or opaque. Herein specifically glass or sapphire substrates are used, however the instant disclosure is not so limited. An indium tin oxide (ITO) layer 114 may be disposed over the substrate 116. A hole-transport layer (HTL) 112 may be disposed over the ITO layer 114. The HTL 112 may be implemented using poly(4-butyl-triphenylamine-4′,4″-diyl) (polyTPD), and may be approximately 15 nm thick. The molecular structure of polyTPD is shown in FIG. 2A. A perovskite layer 110 may be disposed over the HTL 112. The perovskite may have the chemical formula MAPbI₃, where MA is methylammonium. The perovskite layer 110 may be approximately 40 nm thick. The perovskite layer 110 may be prepared using an established in-situ perovskite nanocrystalline film preparation technique. The addition of 20 mol % bulky benzylammonium iodide additives allowed for smooth (about 1 nm surface roughness), pinhole free perovskite thin films in which the 3D MAPbI₃ tetragonal crystal structure was not altered.

An electron-transport layer (ETL) 108 may be disposed over the perovskite layer 110. The ETL 108 may be implemented using phenyldi(pyren-2-yl)phosphine oxide (POPy₂), and may be approximately 40 nm thick. The molecular structure of POPy₂ is shown in FIG. 2C. An electrode 106 may be disposed over the ETL 108. The electrode 106 may be implemented using silver (Ag). Electrodes may be composed of metals or metal substitutes. Herein the term “metal” encompasses both materials composed of an elementally pure metal, and also metal alloys which are materials composed of two or more elementally pure metals. The term “metal substitute” refers to a material that is not a metal within the normal definition, but which has metal-like properties such as conductivity. Examples of metal substitutes include doped wide-bandgap semiconductors, degenerate semiconductors, conducting oxides, and conductive polymers. Electrodes may comprise a single layer or multiple layers (a “compound” electrode), and may be transparent (e.g. transparent conducting oxide), semi-transparent (e.g. thin metal), or opaque.

Finally, a heat spreader 104 may be disposed over the electrode 106, and a heat sink 102 may be disposed over the heat spreader 104.

Four thermal management strategies that can be used to reduce Joule heating and facilitate heat dissipation are disclosed below.

### I. First Thermal Management Strategy

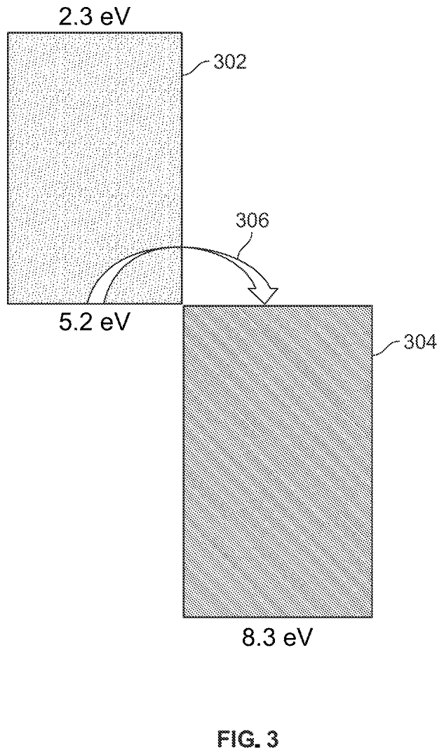

First, the ETL and HTL can be doped to increase device conductivity and reduce Joule heating. Specifically, POPy₂, i.e. the ETL 108, can be n-doped with the molecular reductant (pentamethylcyclopentadienyl)(1,3,5-trimethylbenzene)ruthenium dimer ([RuCp*Mes]₂). And polyTPD, i.e. the HTL 112, can be p-doped with the electron-acceptor molecule 2,3,5,6-tetrafluoro-7,7,8,8-tetracyanoquinodimethane (F₄-TCNQ). The molecular structure for F₄-TCNQ is shown in FIG. 2B and the molecular structure for [RuCp*Mes]₂ is shown in FIG. 2D. The p-doping mechanism of F₄-TCNQ for polyTPD follows traditional charge-transfer doping mechanisms for organic molecules. FIG. 3 is an energy-level diagram illustrating p-doping mechanism of F₄-TCNQ for polyTPD according to one embodiment. As shown in FIG. 3, the energy level of F₄-TCNQ 304 facilitates electron transfer 306 from polyTPD 302. The n-doping mechanism of [RuCp*Mes]₂ for POPy₂ is detailed in the publication X. Lin, B. Wegner, K. M. Lee, M. A. Fusella, F. Zhang, K. Moudgil, B. P. Rand, S. Barlow, S. R. Marder, N. Koch, A. Kahn, Nat. Mater. 2017, 16, 1209, which is incorporated by reference herein in its entirety. After doping, conductivity increased from approximately 10⁻⁸ to approximately 10⁻² S/m for the POPy₂ ETL and from approximately 0.01 to 0.04 S/m for the polyTPD HTL.

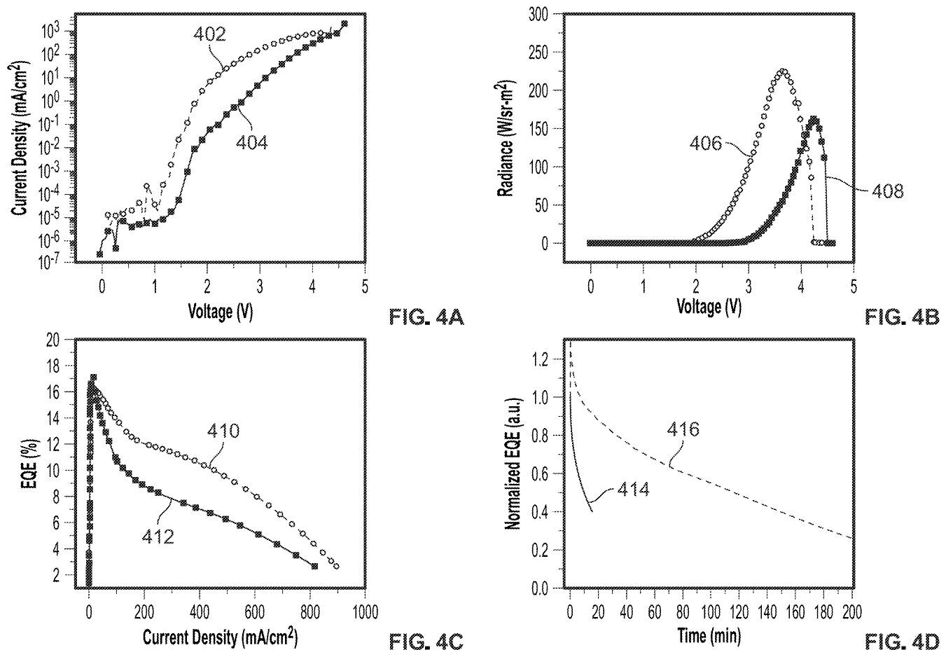

Performance of doped and undoped perovskite devices can be compared. FIG. 4A is a graph illustrating current density-voltage curves for doped and undoped perovskite LEDs according to certain embodiments. Comparing the curve 402 for doped devices against the curve 404 for undoped devices, it can be seen that a marked increase in current density occurs at certain voltages. FIG. 4B is a graph illustrating radiance-voltage curves for doped and undoped perovskite LEDs according to certain embodiments. Similarly, comparing the curve 406 for doped devices against the curve 408 for undoped devices, it can be seen that a marked increase in radiance also occurs at certain voltages.

FIG. 4C is a graph illustrating EQE-current density curves for doped and undoped perovskite LEDs according to certain embodiments. Comparing the curve 410 for doped devices against the curve 412 for undoped devices shows that EQE roll-off is much reduced. Similar peak EQEs of 17.0% and 16.4% are achieved for undoped and doped devices, respectively. This indicates that the electron-hole balance is not altered significantly for the optimized doping conditions of the ETLs and HTLs. However, it was experimentally observed that higher doping concentration in the HTLs correlated with reduced EQEs.

FIG. 4D is a graph illustrating lifetime tests for doped and undoped perovskite LEDs according to certain embodiments. As shown in the figure, device lifetime increases dramatically after doping, likely due to reduced Joule heating. FIG. 4D shows T₅₀—the time taken for EQE or light intensity to drop to half of the device's initial value. As shown by curve 414, the T₅₀ for undoped devices is approximately 10 minutes. But curve 416 shows that the T₅₀ for doped devices is approximately 117 minutes. This represents an order-of-magnitude improvement for doped devices. It should be noted that the above improvements may be due to other mechanisms besides reduced Joule heating, such as fluorine-induced hydrogen bond formation with the ammonium hydrogen in MAPbI₃ perovskites at the HTL/perovskite interface.

### II. Second Thermal Management Strategy

Instead of or in addition to the first thermal management strategy above, the second thermal management strategy is to attach heat spreader 104 and heat sink 102 on top of the electrode 106 (shown in FIG. 1) and/or use more thermally conductive sapphire wafers as the substrate 116 instead of the typical glass. In one embodiment, the heat spreader 104 may be a graphite sheet that is approximately 50 μm thick, having thermal conductivity of 1300 W/(m*K), together with an insulating acrylic adhesive layer that is approximately 6 μm thick. The insulating acrylic adhesive layer is used to prevent potential shorts. In another embodiment, the heat spreader 104 may be a polycrystalline diamond that is approximately 300 μm thick, having thermal conductivity greater than 2000 W/(m*K). The heat sink 102 may be metallic, for example may be a copper bar. Performance of perovskite LEDs implementing the second thermal management strategy is then experimentally examined.

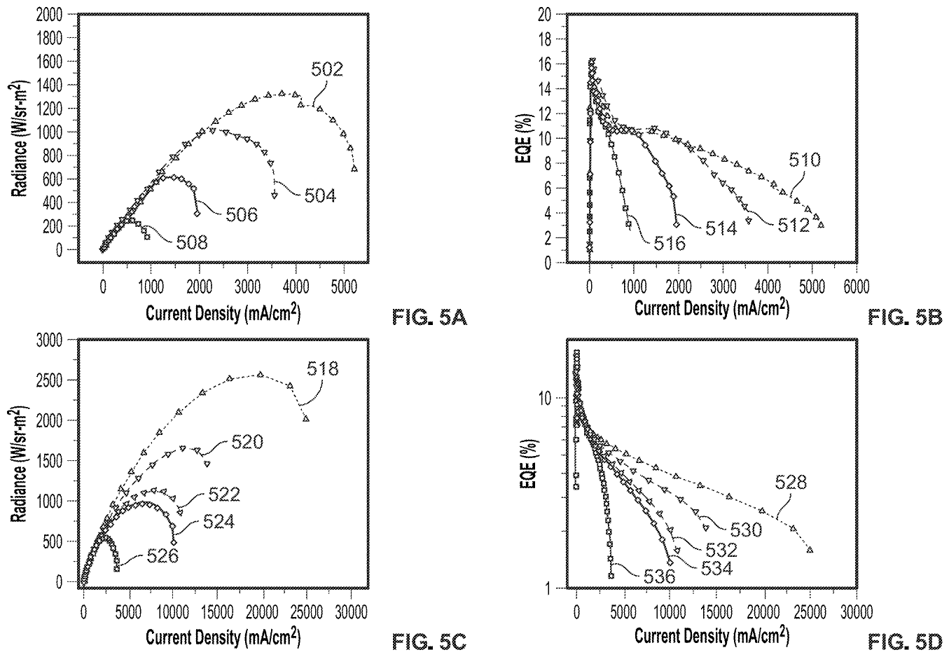

FIG. 5A is a graph illustrating radiance-current density curves for perovskite LEDs with various geometries, substrate, and with or without heat spreaders and heat sinks according to certain embodiments. Curve 502 is for a device having 1×2.5 mm² device area, sapphire substrate, and graphite heat spreader. Curve 504 is for a device having 1×2.5 mm² device area, glass substrate, and graphite heat spreader. Curve 506 is for a device having 1×2.5 mm² device area, glass substrate, and no heat spreader. Curve 508 is for a device having 4×2.5 mm² device area, glass substrate, and no heat spreader. FIG. 5B is a graph illustrating EQE-current density curves of perovskite LEDs with various geometries, substrate, and with or without heat spreaders and heat sinks according to certain embodiments. Curve 510 is for a device having 1×2.5 mm² device area, sapphire substrate, and graphite heat spreader. Curve 512 is for a device having 1×2.5 mm² device area, glass substrate, and graphite heat spreader. Curve 514 is for a device having 1×2.5 mm² device area, glass substrate, and no heat spreader. Curve 516 is for a device having 4×2.5 mm² device area, glass substrate, and no heat spreader. The devices that included heat spreaders also had corresponding heat sinks, whereas the devices that did not include heat spreaders also did not have heat sinks. The 2.5 or 10 mm² active areas are defined by the overlap between the ITO layers 114 and the Ag electrodes 106.

As shown in FIGS. 5A and 5B, performance is very similar for devices with or without applying the second thermal management strategy when driven below 500 mA/cm². However, device implementing the second thermal management strategy exhibit improved performance at higher current densities. When operated at current densities above 500 mA/cm², Joule heating is the dominant factor for the rapid EQE roll-off for devices without thermal management, whereas devices with improved thermal management are able to operate beyond 5000 mA/cm² with significantly reduced EQE roll-off, for example with an EQE of 10% being maintained at 2000 mA/cm². As shown by curve 502, a maximum radiance of 1323 W/(sr*m²) at a current density of 3.7 A/cm² is achieved. To the inventors' knowledge, this is the first report of perovskite LEDs reliably operating in the A/cm² range, which shows the potential of perovskites in high-power applications such as lighting, microLEDs, or electrically pumped lasers.

### III. Third Thermal Management Strategy

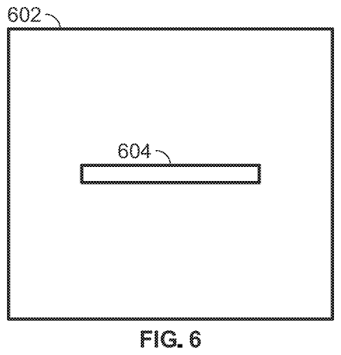

Instead of or in addition to the first and second thermal management strategies above, the third thermal management strategy is to optimize the device geometry of the perovskite LEDs. Specifically, the device area of the perovskite LEDs may be adjusted to be in a narrow line-shape to reduce total power consumption and increase heat dissipation. A performance comparison between 10 and 2.5 mm² area perovskite LEDs in FIGS. 5A and 5B confirms that device area plays a significant role in heat dissipation. That is, as shown in FIGS. 5A and 5B, the larger device corresponding to curves 508 and 516 exhibits worse performance. FIG. 6 is a schematic diagram illustrating a SiO₂ patterning layer with a hole that defines device area according to one embodiment. As shown in FIG. 6, the SiO₂ patterning layer 602 include an aperture 604. The aperture 604 may have the dimensions of 4 μm×1 mm. The aperture 604 is not shown in scale in FIG. 6. The SiO₂ patterning layer 602 with the aperture 604 can then be used to prepare a perovskite device with a 4 μm×1 mm line-shape current aperture geometry that is on a sapphire substrate and with a graphite heat spreader and a copper heat sink. Although the device area is 4 μm×1 mm in this embodiment, the instant disclosure is not so limited. For example, the longer dimension of the device area may be at least 100 times greater than the shorter dimension, and preferably may be 250 times greater.

FIG. 5C is a graph illustrating radiance-current density curves for perovskite LEDs with sapphire substrate, various geometries, and with or without heat spreaders and heat sinks according to certain embodiments. Curve 518 is for a device having 4 μm×1 mm device area and graphite heat spreader. Curve 520 is for a device having 4 μm×1 mm device area and diamond heat spreader. Curve 522 is for a device having 4 μm×1 mm device area and no heat spreader. Curve 524 is for a device having 40 μm×1 mm device area and no heat spreader. Curve 526 is for a device having 1 mm×1 mm device area and no heat spreader. FIG. 5D is a graph illustrating EQE-current density curves of perovskite LEDs with sapphire substrate, various geometries, and with or without heat spreaders and heat sinks according to certain embodiments. Curve 528 is for a device having 4 μm×1 mm device area and graphite heat spreader. Curve 530 is for a device having 4 μm×1 mm device area and diamond heat spreader. Curve 532 is for a device having 4 μm×1 mm device area and no heat spreader. Curve 534 is for a device having 40 μm×1 mm device area and no heat spreader. Curve 536 is for a device having 1 mm×1 mm device area and no heat spreader.

As shown in FIGS. 5C and 5D, the device having 4 μm×1 mm device area, graphite heat spreader, and a copper heat sink reached a maximum radiance of 2555 W/(sr*m²) and a maximum current density of 25 A/cm². This size-dependent performance improvement indicates that micrometer-sized perovskite LEDs might be promising in practical display and lighting applications. Also as shown in FIGS. 5C and 5D, the graphite heat spreader performed better than the diamond heat spreader, possibly because the soft adhesive layer forms better thermal contact to the LED than the rigid diamond.

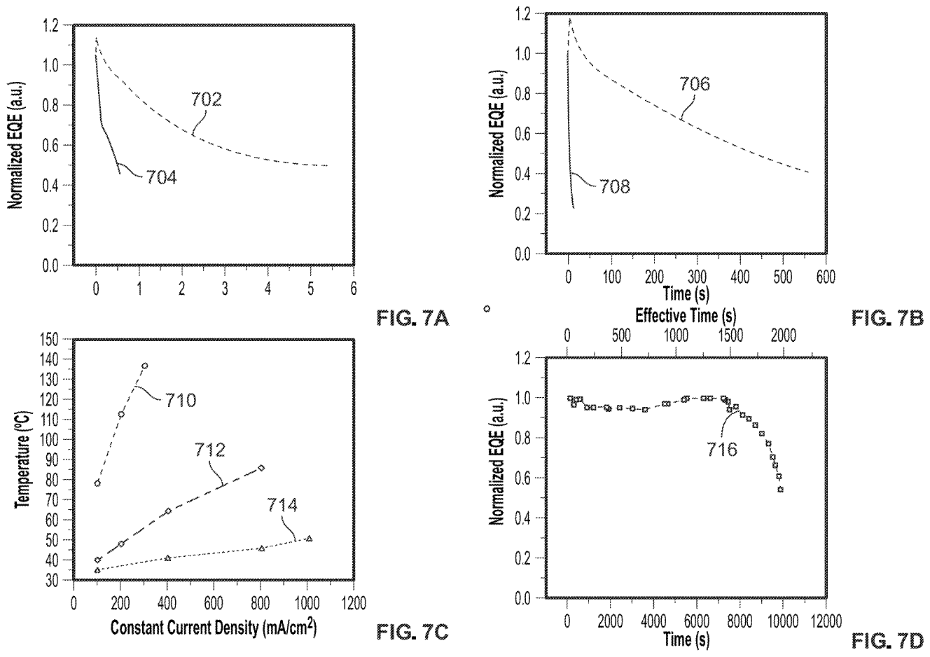

Improvements in operational lifetime for devices implementing these thermal management strategies are also studied. FIG. 7A is a graph illustrating time evolution of the normalized EQE of perovskite LEDs at a constant current density of 100 mA/cm² according to certain embodiments. Curve 702 is for a device having 1×2.5 mm² device area, glass substrate, and graphite heat spreader, and curve 704 is for a device having 1×2.5 mm² device area, glass substrate, and no graphite heat spreader. As shown in the figure, when driven at a constant current density of 100 mA/cm² (corresponding to an initial radiance of 75 W/(sr*m²)), an order-of-magnitude improvement in operational lifetime (T₅₀ from 0.52 to 5.45 hours) is achieved after attaching a graphite heat spreader and a copper heat sink.

The thermal management strategies play a more significant role at higher current densities, conditions where more heat is generated. FIG. 7B is a graph illustrating time evolution of the normalized EQE of perovskite LEDs at a constant current density of 800 mA/cm² according to certain embodiments. Curve 706 is for a device having 1×2.5 mm² device area, glass substrate, and graphite heat spreader, and curve 708 is for a device having 1×2.5 mm² device area, glass substrate, and no graphite heat spreader. As shown in FIG. 7B, a hundredfold improvement in operational lifetime (T₅₀ from 4 to 436 seconds) is observed when the devices are driven at 800 mA/cm² (corresponding to an initial radiance of 450 W/(sr*m²)).

### IV. Fourth Thermal Management Strategy

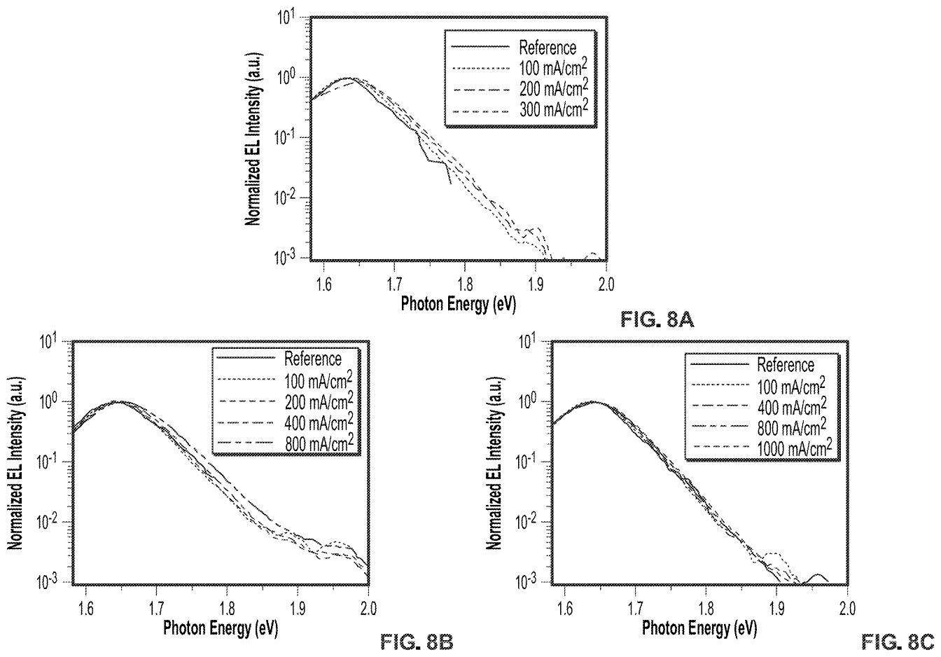

Instead of or in addition to the first, second, and third thermal management strategies above, the fourth thermal management strategy is to drive the perovskite devices with electrical pulses instead of a continuous electrical bias. FIG. 7C is a graph illustrating carrier temperatures extracted from high-energy EL tails according to the generalized Planck equation for perovskite LEDs with various geometries and heat spreaders as a function of constant current density according to certain embodiments. Curve 710 is for a device having 4×2.5 mm² device area and no heat spreader, curve 712 is for a device having 1×2.5 mm² device area and no heat spreader, and curve 714 is for a device having 1×2.5 mm² device area and a graphite heat spreader. FIG. 8A is a graph illustrating high energy portion of the EL spectra of perovskite LEDs with device areas of 10 mm² driven at various constant current densities according to certain embodiments. FIG. 8B is a graph illustrating high energy portion of the EL spectra of perovskite LEDs with device areas of 2.5 mm² driven at various constant current densities according to certain embodiments. FIG. 8C is a graph illustrating high energy portion of the EL spectra of perovskite LEDs with device areas of 2.5 mm² with graphite heat spreader and copper heat sink driven at various constant current densities according to certain embodiments. FIG. 8A corresponds to curve 710, FIG. 8B corresponds to curve 712, and FIG. 8C corresponds to curve 714.

As shown in FIG. 7C, heat builds up significantly for devices without applying thermal management strategies. For example, carrier temperature increases dramatically to approximately 110° C. for the 10 mm² LED driven at 200 mA/cm². In contrast, carrier temperature maintains a moderate level of approximately 50° C. for the 2.5 mm² LED with a graphite heat spreader, even when driven at a high current density of 1000 mA/cm².

To further reduce the influence of heat buildup on device lifetime, device stability was tested using electrical pulses with a pulsing width (PW) of 2 μs and a duty cycle of 20%. This allows the device to cool between each pulse. FIG. 7D is a graph illustrating time evolution of the normalized EQE of a perovskite LED under pulsed operation at 800 mA/cm² according to an embodiment. Here, the device used has a device area of 1×1 mm², a sapphire substrate, and graphite heat spreader. The pulse repetition rate was 100 kHz. Curve 716 shows no EQE degradation during the first 7500 seconds, corresponding to 1500 seconds of effective time, i.e. total pulse “on” time, which is significantly longer than that under continuous current drive.

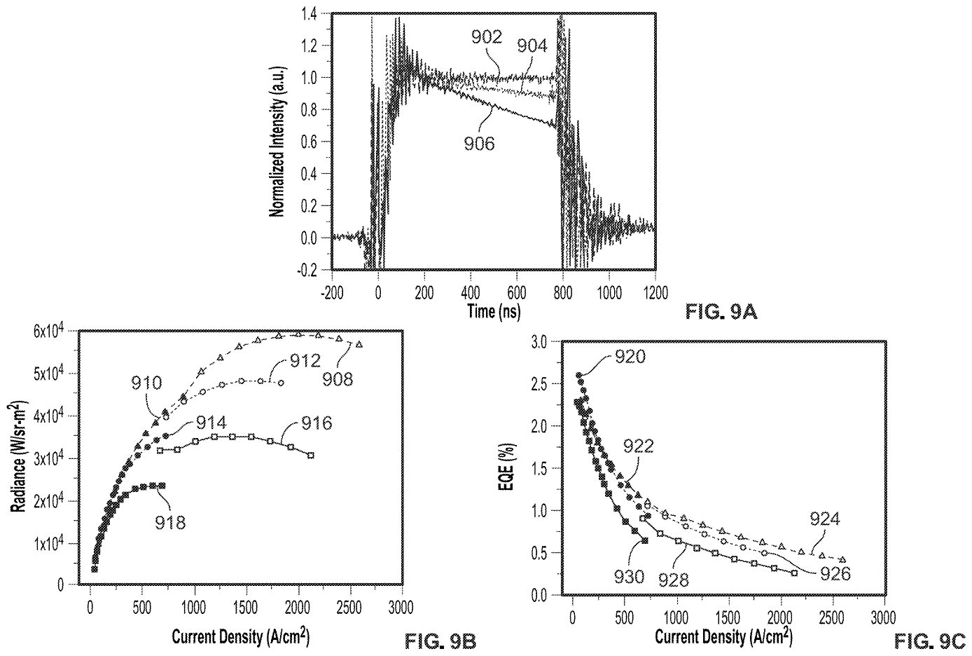

The experiment documented by FIG. 7D shows that driving devices with electrical pulses may also be an effective strategy to improve device performance. Therefore the effects of thermal management for perovskite LEDs operated at extremely high current densities by driving the perovskite LEDs with electrical pulses are further studied. FIG. 9A is a graph illustrating normalized radiance-time curves for various perovskite LEDs driven by a 700 A/cm² pulse with a pulsing width of 800 ns according to certain embodiments. Curve 902 is for a device having sapphire substrate and a graphite heat spreader. Curve 904 is for a device having sapphire substrate and no graphite heat spreader. Curve 906 is for a device having glass substrate and no graphite heat spreader. As shown by curve 906, EL intensity decreased to approximately 70% of its initial value within the 800 ns pulse duration for a device fabricated on glass substrate due to significant Joule heating even within such a short pulse. In contrast, only a 10% decrease in EL intensity is observed for a device fabricated on sapphire substrate, and no EL intensity change is observed over the pulse for a device with a graphite heat spreader. Note that the high frequency noise in the radiance measurements of the pulsed devices is purely due to incomplete electromagnetic shielding of the detection circuit. The noise has been left unfiltered in order to illustrate the fast response time of the device.

FIG. 9B is a graph illustrating radiance-current density curves of various perovskite LEDs driven in pulsed mode according to certain embodiments. Curve 908 is for a device having sapphire substrate and a graphite heat spreader, and driven with pulses having PW of 250 ns. Curve 910 is for a device having sapphire substrate and a graphite heat spreader, and driven with pulses having PW of 800 ns. Curve 912 is for a device having sapphire substrate and no heat spreader, and driven with pulses having PW of 250 ns. Curve 914 is for a device having sapphire substrate and no heat spreader, and driven with pulses having PW of 800 ns. Curve 916 is for a device having glass substrate and no heat spreader, and driven with pulses having PW of 250 ns. And finally curve 918 is for a device having glass substrate and no heat spreader, and driven with pulses having PW of 800 ns.

FIG. 9C is a graph illustrating EQE-current density curves of various perovskite LEDs driven in pulsed mode according to certain embodiments. Curve 924 is for a device having sapphire substrate and a graphite heat spreader, and driven with pulses having PW of 250 ns. Curve 922 is for a device having sapphire substrate and a graphite heat spreader, and driven with pulses having PW of 800 ns. Curve 926 is for a device having sapphire substrate and no heat spreader, and driven with pulses having PW of 250 ns. Curve 920 is for a device having sapphire substrate and no heat spreader, and driven with pulses having PW of 800 ns. Curve 928 is for a device having glass substrate and no heat spreader, and driven with pulses having PW of 250 ns. And finally curve 930 is for a device having glass substrate and no heat spreader, and driven with pulses having PW of 800 ns.

As shown in FIGS. 9B and 9C, significantly higher radiances and EQEs are achieved after applying at least some of the four thermal management strategies disclosed above, especially at high current densities exceeding 1 kA/cm². Notably, an EQE of approximately 1% at 1 kA/cm² and a maximum radiance of 59 kW/(sr*m²) at 2 kA/cm² were achieved. Although the disclosed embodiments are driven with pulses having PWs of 250 ns and 800 ns, these PWs are only examples, and the instant disclosure is not limited to the disclosed embodiments. For example, perovskite LEDs may be driven with pulses having PW of greater than or equal to 1 ns.

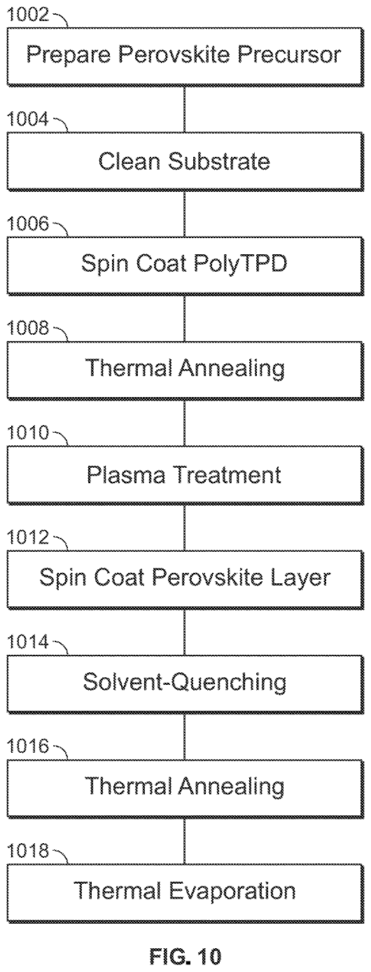

FIG. 10 is a flowchart illustrating a method of fabricating a perovskite LED according to an embodiment. First, a perovskite precursor solution was prepared at step 1002 in a N₂ filled glovebox by dissolving methylammonium iodide (MAI), PbI₂, and benzylammonium iodide (PMAI) in dimethylformamide (DMF) to obtain 0.2 m MAPbI₃ with 0.04 m PMAI as an additive. The precursor solution was used within three hours of fully dissolving. ITO coated glass or sapphire substrates with a sheet resistance of 15 Ω/sq were used. At step 1004, the substrates were cleaned in air sequentially with soapy water, deionized water, acetone, and isopropyl alcohol, and were then treated with O₂ plasma for 10 minutes prior to film deposition in the N₂ filled glovebox. At step 1006, polyTPD (4.8 mg/mL in chlorobenzene), with or without the F₄-TCNQ dopant (0.2 mg/mL in chlorobenzene), was spin coated on top of ITO at 1500 rpm for 70 seconds, followed by thermal annealing at 150° C. for 20 minutes at step 1008. At step 1010, the not-yet-completed devices were then treated with O₂ plasma for 15 seconds to improve wettability. The perovskite layer is then spin-coated onto the polyTPD layer at 6000 rpm at step 1012. A solvent-quenching step 1014 was performed after 4 seconds by dropping toluene (100 μL) on the spinning devices. The devices were then annealed again at 70° C. for 5 minutes at step 1016. Then, 10 nm undoped POPy₂ or 30 nm POPy₂ doped with [RuCp*Mes]₂ (in a ratio of 6:1) and 100 nm Ag electrodes were thermally evaporated on top of the perovskite films to complete device fabrication at step 1018.

For the undoped ETL control devices, after the deposition of 30 nm undoped POPy₂, another 10 nm doped POPy₂ were deposited to keep the same ETL thickness and carrier-injection barrier from the Ag electrodes. All devices were illuminated at one-sun intensity (AM 1.5G, 100 mW/cm²) using a solar simulator for 10 minutes to photoactivate the n-dopant. As explained above, the device area was defined either by the overlap between ITO and Ag electrodes, or by a patterned insulating SiO₂ (120 nm) layer. To pattern the SiO₂ onto the ITO, photoresist (AZ1518) was spin-coated at 4000 rpm for 40 second on the ITO/glass or ITO/sapphire substrate. After baking the photoresist layer at 95° C. for 60 seconds, positive photolithography was carried out, followed by development for 60 seconds. An insulating 120 nm-thick SiO₂ layer was grown by plasma enhanced chemical vapor deposition at 70° C. The small-area LED pattern was then obtained by lift-off and then soaking the devices in photoresist remover (AZ1165) at 80° C. overnight.

Embodiments of the invention may be fabricated using the process disclosed in connection with FIG. 10, as described above, and/or other processes such as vacuum deposition, spin coating, organic vapor-phase deposition, inkjet printing, and other methods known in the art.

Beyond applications such as lighting or displays, metal halide perovskites hold great potential as gain media for realizing nonepitaxial electrically driven laser diodes. Conventionally, EQE roll-off and device degradation significantly hold back the achievement of high current densities required for electrically driven lasing. Based on an estimated threshold carrier density nₜₕ≈8×1017 cm⁻³ for a MAPbI₃ perovskite laser in a distributed feedback resonator, the threshold current density can be estimated by the following formula:

$${J}_{th} \approx q {d}_{0} B {n}_{t h}^{2} / {η}_{IQE}$$

where “q” is the elementary charge, d₀ is the thickness of the perovskite layer and is approximately 40 nm in the disclosed embodiments, B at approximately 4×10⁻¹⁰ cm³/s is the bimolecular radiative rate constant for MAPbI₃, and η_{IQE} is the internal quantum efficiency of the perovskite LED. Based on atypical outcoupling efficiency φ_{oc}=η_{EQE}/η_{IQE}≈0.2, the corresponding EQE-current density product at the lasing threshold would be η_{EQE}Jₜₕ or approximately 33 A/cm². In comparison, using the disclosed thermal management strategies a peak η_{EQE}Jₜₕ of approximately 10 A/cm² was reached, demonstrating that the injection level needed for lasing is realistically feasible. It should be noted, however, the elevated carrier temperature will further increase the lasing threshold. Although no sign of stimulated emission was observed, it is demonstrated that proper thermal management is key for the development of electrically driven perovskite lasers.

As described above, the disclosed invention, in one or more embodiments, provides a perovskite LED implementing one or more thermal management strategies. These thermal management strategies significantly improve device performance, including limiting EQE roll-off and extending device lifetime.

It should be understood that various changes, substitutions, and alterations may be readily ascertainable by those skilled in the art and may be made herein without departing from the spirit and scope of the disclosed invention as defined by the following claims.

What is claimed is:

1. A perovskite light emitting diode, comprising:
a sapphire substrate;
a hole-transport layer disposed over the substrate, the hole-transport layer comprising poly(4-butyl-triphenylamine-4′, 4″-diyl) (polyTPD) and is p-doped with 2,3,5,6-tetrafluoro-7,7,8,8-tetracyano-quinodimethane (F₄-TCNQ);
a perovskite layer disposed over the hole-transport layer;
an electron-transport layer disposed over the perovskite layer, the electron-transport layer comprising phenyldi(pyren-2-yl)phosphine oxide (POPy₂) and is n-doped with (penta-methylcyclopentadienyl)(1,3,5-trimethylbenzene)ruthenium dimer ([RuCp*Mes]₂);
an electrode disposed over the electron-transport layer;
a heat spreader disposed over the electrode, the heat spreader comprising a graphite sheet with an insulating acrylic adhesive layer or a polycrystalline diamond;
a metallic heat sink disposed over the heat spreader; and
a control circuit configured to drive the perovskite light emitting diode with electrical pulses,
wherein a device area of the perovskite light emitting diode is in a narrow line shape.

2. A perovskite light emitting diode, comprising:
a substrate;
a hole-transport layer disposed over the substrate;
a perovskite layer disposed over the hole-transport layer;
an electron-transport layer disposed over the perovskite layer; and
an electrode disposed over the electron-transport layer,
wherein the perovskite light emitting diode is thermally managed to reduce Joule heating and increase heat dissipation.

3. The perovskite light emitting diode of claim 2, wherein the hole-transport layer and/or the electron-transport layer is doped to increase device conductivity.

4. The perovskite light emitting diode of claim 3, wherein the hole-transport layer comprises poly(4-butyl-triphenylamine-4′, 4″-diyl) (polyTPD).

5. The perovskite light emitting diode of claim 4, wherein the polyTPD is p-doped with 2,3,5,6-tetrafluoro-7,7,8,8-tetracyano-quinodimethane (F₄-TCNQ).

6. The perovskite light emitting diode of claim 3, wherein the electron-transport layer comprises phenyldi(pyren-2-yl)phosphine oxide (POPy₂).

7. The perovskite light emitting diode of claim 6, wherein the POPy₂ is n-doped with (penta-methylcyclopentadienyl)(1,3,5-trimethylbenzene)ruthenium dimer ([RuCp*Mes]₂).

8. The perovskite light emitting diode of claim 2, wherein the substrate has a thermal conductivity greater than a thermal conductivity of glass.

9. The perovskite light emitting diode of claim 2, wherein the substrate comprises sapphire.

10. The perovskite light emitting diode of claim 2, further comprising:
a heat spreader disposed over the electrode; and
a heat sink disposed over the heat spreader.

11. The perovskite light emitting diode of claim 10, wherein the heat spreader comprises:
a graphite sheet with an insulating acrylic adhesive layer; or
a polycrystalline diamond, and
wherein the heat sink comprises metal.

12. The perovskite light emitting diode of claim 2, wherein a device area of the perovskite light emitting diode is less than 2.5 mm².

13. The perovskite light emitting diode of claim 12, wherein the device area has a first dimension and a second dimension, and
wherein the first dimension is at least 100 times greater than the second dimension.

14. The perovskite light emitting diode of claim 13, wherein the first dimension is 1 mm and the second dimension is 4 μm.

15. The perovskite light emitting diode of claim 2, further comprising a control circuit configured to drive the perovskite light emitting diode with electrical pulses.

16. The perovskite light emitting diode of claim 15, wherein the electrical pulses have a pulsing width (PW) of greater than or equal to 1 ns.

17. A method of fabricating a perovskite light emitting diode, comprising:
preparing a perovskite precursor solution by dissolving methylammonium iodide (MAI), lead iodide (PbI₂), and benzylammonium iodide (PMAI) in dimethylformamide (DMF);
cleaning a substrate and treating the substrate with O₂ plasma;
spin-coating a hole-transport layer onto the substrate followed by thermal annealing;
spin-coating a perovskite layer onto the hole-transport layer;
solvent-quenching the perovskite light emitting diode prior to deposition of an electron-transport layer; and
thermally evaporating the electron-transport layer onto the perovskite layer.

18. The method of claim 17, wherein the hole-transport layer comprises poly(4-butyl-triphenylamine-4′, 4″-diyl) (polyTPD) and is p-doped with 2,3,5,6-tetrafluoro-7,7,8,8-tetracyano-quinodimethane (F₄-TCNQ).

19. The method of claim 17, wherein the electron-transport layer comprises phenyldi(pyren-2-yl)phosphine oxide (POPy₂) and is n-doped with (penta-methylcyclopentadienyl)(1,3,5-trimethylbenzene)ruthenium dimer ([RuCp*Mes]₂).

20. The method of claim 19, further comprising photoactivating the [RuCp*Mes]₂ by illuminating the perovskite light emitting diode at one-sun intensity for 10 minutes.
